(19) United States
(12) Patent Application Publication
(10) Pub. No.: US 2006/0210887 A1
(43) Pub. Date: Sep. 21, 2006

(54) Lithography mask and methods for producing a lithography mask

(75) Inventors: Thomas Henkel, Dresden (DE); Roderick Kohle, Ottobrunn (DE); Christoph Nolscher, Nurnberg (DE); Kerstin Renner, Dresden (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munchen (DE)

(21) Appl. No.: 11/366,027

(22) Filed: Mar. 2, 2006

(30) Foreign Application Priority Data
Mar. 3, 2005 (DE) 10 2005 009 805.3

(51) Int. Cl. G03C 5/00; G03F 1/00

(52) U.S. Cl. 430/5; 430/322; 430/323; 430/324

(57) ABSTRACT

Lithography mask for the lithographic patterning of a resist layer on a substrate having first regions, in which the lithography mask has a nontransparent layer, and second and third regions, which differ in terms of the optical thickness of the lithography mask and in which the lithography mask is at least semitransparent. The lithography mask comprises a first section having a plurality of second regions and a plurality of third regions, which are arranged alternately and surrounded by a first region, for the lithographic production of resist openings at distances which are less than a predetermined limit distance. Furthermore, the lithography mask comprises a second section having a multiplicity of third regions, each of which is surrounded by a second region surrounded by a multiply contiguous first region, for the lithographic production of resist openings at distances which are greater than a predetermined limit distance.

### CLAIM FOR PRIORITY

This application claims the benefit of priority to German Application No. 10 2005 009 805.3, filed in the German language on Mar. 3, 2005, the contents of which are hereby incorporated by reference.

### TECHNICAL FIELD OF THE INVENTION

The present invention relates to a lithography mask for the lithographic production of dense and isolated contact holes, and to methods which are particularly suitable for producing such a lithography mask.

### BACKGROUND OF THE INVENTION

In microelectronic or micromechanical components, structures at small distances from one another, in particular at distances which are less than the wavelength used for their lithographic production, are referred to as dense structures. Structures at larger distances from one another are referred to as semi-isolated or isolated structures. In the fabrication of a microelectronic or micromechanical component, a minimum number of process steps is advantageous inter alia for cost reasons. Therefore, it is desirable to produce dense, semi-isolated and isolated structures microlithographically in one and the same step.

One example of structures which may occur in dense, semi-isolated or isolated fashion is contact holes or passage hole conductors for connecting different wiring planes or wiring planes to the component layer. There typically exist on one and the same chip regions in which contact holes are present in a large number on a small area and are thus at small distances from one another (dense structures), and other regions in which are arranged only few contact holes at large distances from one another. It is desirable to produce all the contact holes within a plane simultaneously, that is to say by imaging of one and the same lithography mask.

Dense structures are conventionally produced by alternating phase shift masks (altPSM). An altPSM has first and second regions, which differ in terms of their optical thickness such that light having a predetermined wavelength which is transmitted through a first region of the altPSM and light from the same light source which is transmitted through an adjacent second region have a phase difference, which is preferably 180°+/−60°. Adjacent structures, for example contact holes, trenches or else other punctiform or linear structures, are produced by corresponding regions having different optical thicknesses on the lithography mask. During the imaging of the lithography mask onto a photoresist, each phase jump between two adjacent first and second regions produces a dark image region or image region having a low light intensity, by which the adjacent structures are distinctly separated.

Half tone phase shifting masks (HTPSM) are used for semi-dense or semi-isolated and isolated structures; in these masks the first and second regions differ not only in terms of the phase of the transmitted light but also in terms of their transparency or transmissivity.

DE 100 01 119 A1 describes a lithography mask which is formed in each case as alternating phase shift mask in zones in which the distances between adjacent light-transmissive regions in at least one spatial direction lie below a predetermined limit distance. In zones in which the distances between the adjacent light-transmissive regions are greater than the limit distance, the phase shift mask is formed in each case as half tone phase shifting mask or chromeless phase shift mask.

The article “Alternating Phase Shift Masks for Contact Patterning” by R. Schenker et al. (Optical Microlithography XVI, Anthony Yen, Editor, Proceedings of SPIE Vol. 50/40 (2003)) mentions a combined use of alternating phases for dense contacts and phase-shifted auxiliary structures for semi-dense and isolated contacts. Said phase-shifted auxiliary structures comprise a plurality of transparent areas which are spaced apart and through which light is transmitted with different phases, and which are surrounded by a nontransparent region of the lithography mask.

EP 0 451 307 A1 describes the fabrication of a phase shift mask with a mask pattern made of a light-absorbing material on a carrier made of quartz. The thickness of the carrier has different thicknesses in a first region and a second region, in which the mask pattern is not arranged. For fabrication purposes, firstly the mask pattern is produced. The first region is covered by photoresist. In the second region, which is not covered, the carrier is etched in order to reduce its thickness.

The technologies of the documents mentioned have specific disadvantages, in particular for example restrictions with regard to the process window or the permissible parameter ranges during the lithographic imaging of the lithography mask.

A general and fundamental problem is furthermore the fabrication of lithography masks with the required precision, in particular for example with the required relative positional accuracy of nontransparent and transparent regions.

### SUMMARY OF THE INVENTION

The present invention provides an improved lithography mask and also improved methods for producing a lithography mask, for fabricating a semiconductor component and for producing data sets for the production of a lithography mask.

The present invention, in one embodiment, provides on the same lithography mask altPSM sections for dense structures and also, if necessary, sections having 180° phase transitions in nontransparent surroundings (e.g. RIM sections) for semi-isolated and isolated structures. The lithography mask has first, nontransparent regions and also second and third, at least semitransparent regions, which differ in terms of the optical thickness of the lithography mask. In an altPSM section, the lithography mask has a plurality of second regions and a plurality of third regions, which are arranged alternately and surrounded by a first region. In an RIM section, the lithography mask has RIM structures. An RIM structure comprises a third region, which is directly surrounded by a second region, which is in turn surrounded by a multiply contiguous first region. The second region surrounding the third region is preferably multiply contiguous.

In this case, an alternating arrangement means, in particular, that in the case of a linear dense arrangement of structures, the latter are produced alternately by second and third regions of the lithography mask. In the case of an areal dense arrangement of structures, second and third regions are arranged alternately in each case in two directions that are essentially perpendicular to one another, similarly to the black and white areas on a chessboard, but spaced apart from one another. The alternating or alternative arrangement of second and third regions has the effect that generally a third region is arranged closest adjacent to each second region and a second region is arranged closest adjacent to each third region. Within the altPSM section, preferably each second and each third region is singly contiguous.

In another embodiment of the present invention, when producing a lithography mask having nontransparent first regions and at least semitransparent second and third regions, in which the lithography mask has different optical thicknesses, of producing a first resist mask, which is provided for the removal of the nontransparent layer in the second regions, such that it does not cover a third region of the lithography mask at least in a peripheral edge region. By means of a second resist mask, the optical thickness of the lithography mask is changed in the third region, which is covered neither by the second resist mask nor by the nontransparent layer.

The invention has an advantage that even when there is a relative lateral offset between the first and second resist masks, which offset can be avoided with a disproportionate outlay in practice, no residues of the nontransparent layer remain between second and third regions which are intended to adjoin one another. This is of particular importance in the case of lithography masks having the abovementioned RIM structures in which a third region is arranged within a multiply contiguous second region. Therefore, the invention is particularly suitable for the above-described lithography mask having altPSM sections and RIM sections. A further advantage of this invention is that the second resist mask can be produced with a lower lateral resolution. The tolerance range with regard to a relative lateral offset between the two resist masks and with regard to the lateral resolution is determined by the width of the peripheral edge region of the third region which is not covered by the second resist mask.

### BRIEF DESCRIPTION OF THE DRAWINGS

The invention is described in more detail below with reference to the exemplary embodiments and drawings, in which:

FIG. 1 shows a first exemplary embodiment of the present invention.

FIG. 2 shows a second exemplary embodiment of the present invention.

FIG. 3 shows a third exemplary embodiment of the present invention.

FIG. 4 shows a fourth exemplary embodiment of the present invention.

FIGS. 5 and 6 show a fifth exemplary embodiment of the present invention.

FIG. 7 shows a sixth exemplary embodiment of the present invention.

### DETAILED DESCRIPTION OF THE INVENTION

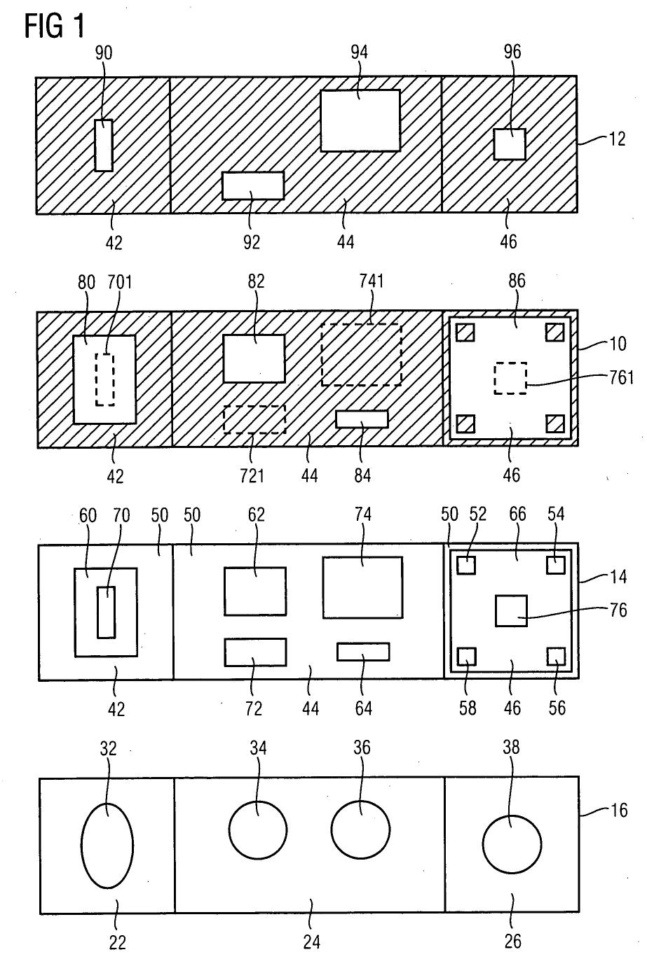

FIG. 1 is a schematic illustration of a first exemplary embodiment of the present invention. It shows schematic plan views of a first resist mask 10, a second resist mask 12, a finished lithography mask 14 fabricated by means of the resist masks 10, 12, and a substrate 16 patterned lithographically by means of the lithography mask 14. The resist masks 10, 12 are produced during the fabrication of the lithography mask 14 on the mask substrate thereof. Afterward, their lateral structures, as described below, are transferred into or onto the mask substrate in order to obtain the lithography mask 14.

The patterned substrate 16 has a first section 22, a second section 24 and a third section 26 each having one or a plurality of contact holes or passage holes 32, 34, 36, 38. The passage holes 32, 34, 36, 38 penetrate through the visible topmost layer of the patterned substrate 16 in order, by way of example, to produce electrically conductive connections between wiring planes which lie above and below this electrically insulating layer. In the first section 22 and in the third section 26, the passage holes 32, 38 are arranged in isolated or semi-isolated fashion, that is to say they are at a large distance from one another which, in particular, is greater or much greater than the wavelength of the light used during the lithographic patterning of the substrate 16. In the second section 24, the passage holes 34, 36 are arranged in dense fashion, that is to say they are at a small distance from one another which, in particular, is less than the wavelength of the light used during a lithographic patterning of the substrate 16.

In a real patterned substrate 16; sections 22, 26 having isolated or semi-isolated structures and sections 24 having dense structures will be significantly more extensive and/or spaced apart further from one another, so that the distances between the isolated structures 32, 38, on the one hand, and the dense structures 34, 36, on the other hand, are also significantly greater than the distances between adjacent dense structures 34, 36 within a second section 24. The relative spatial arrangement of the sections 22, 24, 26 in FIG. 1 was chosen with regard to a clear and space-saving illustration and is therefore not to scale in particular with regard to the distances between dense structures 34, 36, on the one hand, and semi-isolated or isolated structures 32, 38, on the other hand.

In the illustration of the lithography mask 14 for the lithographic patterning of the substrate 16, the customary demagnifying imaging of the lithography mask onto the substrate (for example on a scale of 4:1) has been disregarded. The lithography mask 14 has, in accordance with the patterned substrate 16, a first section 42, a second section 44 and a third section 46, which are deposited onto the first, second and third sections 22, 24, 26, respectively, of the substrate in order to pattern the latter. The lithography mask 14 has first, nontransparent regions 50, 52, 54, 56, 58. In said nontransparent regions, the lithography mask 14 has a thin light-absorbing layer on its surface, which layer is composed of chrome, by way of example. Said first, nontransparent regions 50, 52, 54, 56, 58 preferably have a transmissivity of 1% or less, and particularly preferably a transmissivity of 1 per thousand or less.

Furthermore, the lithography mask 14 has second regions 60, 62, 64, 66 and third regions 70, 72, 74, 76, in which the lithography mask 14 is at least semitransparent, or has a transmissivity of 6% or greater, and preferably a transmissivity of almost 100%. In said second and third regions, the lithography mask 14 preferably does not have the nontransparent layer or has it only with a smaller thickness.

The second regions 60, 62, 64, 66 and the third regions 70, 72, 74, 76 differ by virtue of the optical thickness of the lithography mask 14 such that light having a predetermined wavelength which is transmitted through a second region 60, 62, 64, 66 has, relative to light from the same light source which is transmitted through an adjacent third region 70, 72, 74, 76, a phase difference in a predetermined interval, preferably between 120° and 240°, and particularly preferably a phase difference of 180°.

The lithography mask 14 is preferably fabricated or produced from a mask substrate made of highly transparent material with a thin nontransparent layer that is initially applied over the whole area. The transparent material is preferably quartz glass. The nontransparent layer is composed of chrome, by way of example. The at least semitransparent second and third regions 60, 62, 64, 66, 70, 72, 74, 76 are produced by locally removing the nontransparent layer. In the third regions, the thickness of the transparent material is reduced relative to an adjacent second region by a magnitude
Δ=λ₁·(1±⅓)/(2(n₂−n₁))

In this case, λ₁ is the wavelength of the light used for the lithographic imaging of the finished lithography mask 14 onto the substrate 16 in the medium (e.g. air, nitrogen, vacuum) surrounding the mask, n₁ is the refractive index of the medium surrounding the mask, and n₂ is the refractive index of the material layer, by which the second and third regions differ. This removal of a layer having the thickness Δ is preferably effected by etching and is described in more detail below.

In order to fabricate or produce the lithography mask 14, the mask substrate is patterned with the aid of two resist masks 10, 12. For the production of the resist masks 10, 12, firstly a first data set describing the first resist mask 10 and a second data set describing the second resist mask 12 are produced. Each data set contains all the data required in order, by way of example, by means of an electron beam, ion beam or laser beam, to pattern a resist layer—initially present over the whole area on the mask substrate—(if necessary together with a subsequent development step) such that the corresponding resist mask arises. In particular, each data set defines the number, arrangement, size and form of the openings of the resist mask. In the art a series of data formats for data sets of this type are known which can be produced by design programs and read by electron beam, ion beam or other writing devices for the patterning of the resist in order, by way of example, to correspondingly control the electron beam, ion beam or laser beam.

The first data set describing the first resist mask 10 defines openings 80, 82, 84, 86 in the first resist mask 10, which correspond to the second regions 60, 62, 64, 66 plus a portion of the third regions. In particular, the openings 80, 86 encompass the third regions 70, 76 in the sections 42, 46, which are provided for producing semi-dense or isolated structures 32, 38. The semi-dense or isolated structures 32, 38 are produced by RIM-like structures in which a singly contiguous third region 70, 76 is surrounded by a directly adjoining multiply contiguous second region 60, 66. The dense structures 34, 36 are produced by altPSM structures on the lithography mask 14 which are formed by an alternating arrangement of singly contiguous second and third regions 62, 64, 72, 74 which are in each case directly surrounded by the multiply contiguous first region 50 and adjoin the latter. The first data set describing the first resist mask 10 defines no openings which correspond to third regions 72, 74 in the second section 44 for the production of dense structures 34, 36 or encompass them.

Consequently, the openings 80, 82, 84, 86 of the first resist mask 10 which are defined by the first data set encompass all the second regions 60, 62, 64, 66 and the third regions 70, 76 directly adjoining second regions 60, 66.

The second resist mask 12 is described by a second data set. The second data set defines openings 90, 92, 94, 96 corresponding to the third regions 70, 72, 74, 76.

After the production of the two data sets, firstly the second resist mask 12 is produced on the mask substrate. For this purpose, the mask substrate is firstly coated over the whole area with a resist that can be patterned by means of an electron beam, ion beam or laser beam or in some other way. This resist layer, under the control of the second data set, is then locally exposed or written to by means of an electron beam, ion beam, laser beam or in some other way and is subsequently developed in order to produce the openings 90, 92, 94, 96 in the resist layer. As prescribed by the second data set, the openings 90, 92, 94, 96 correspond to the third regions 70, 72, 74, 76 of the finished lithography mask 14.

The second resist mask 12 then serves as an etching mask. In the region of the openings 90, 92, 94, 96, the nontransparent layer and a layer having the above-described thickness Δ of the transparent material of the mask substrate are removed. This is effected in one etching step using a single etchant or else in two etching steps, the nontransparent layer being removed in a first etching step using a first etchant and the transparent material of the mask substrate being removed in a second etching step using a second etchant. At least the removal of the transparent medium is preferably effected in an anisotropic etching step. In this case, before the second etching step, the resist mask may be removed and the already patterned nontransparent layer may be used as an etching mask for the second etching step.

After the third regions 70, 72, 74, 76 have been produced with the aid of the second resist mask 12 and the second resist mask 12 has been removed again, the first resist mask 10 is produced in a corresponding manner, but under the control of the first data set. The openings 80, 82, 84, 86 produced in the first resist mask 10 encompass, in accordance with the first data set, the second regions 60, 62, 64, 66 and additionally the third regions 70, 76 directly adjoining second regions 60, 66. For illustration purposes, the edges 701, 721, 742, 762 of the third regions 70, 72, 74, 76 already produced relative to the first resist mask 10 are represented by interrupted lines.

The first resist mask 10 then serves as an etching mask for the removal of the nontransparent layer in the second regions 60, 62, 64, 66 defined by the openings 80, 82, 84, 86. The nontransparent layer is preferably removed by means of an etchant which acts selectively and removes the nontransparent layer, but not the transparent material of the mask substrate.

The lithography mask 14 is completed after the removal of the first resist mask 10. It is evident that even when there is a relative lateral offset between the first resist mask 10 and the second resist mask 12, no residues of the nontransparent layer remain between those second regions 60, 66 and those third regions 70, 76 which are intended to directly adjoin one another.

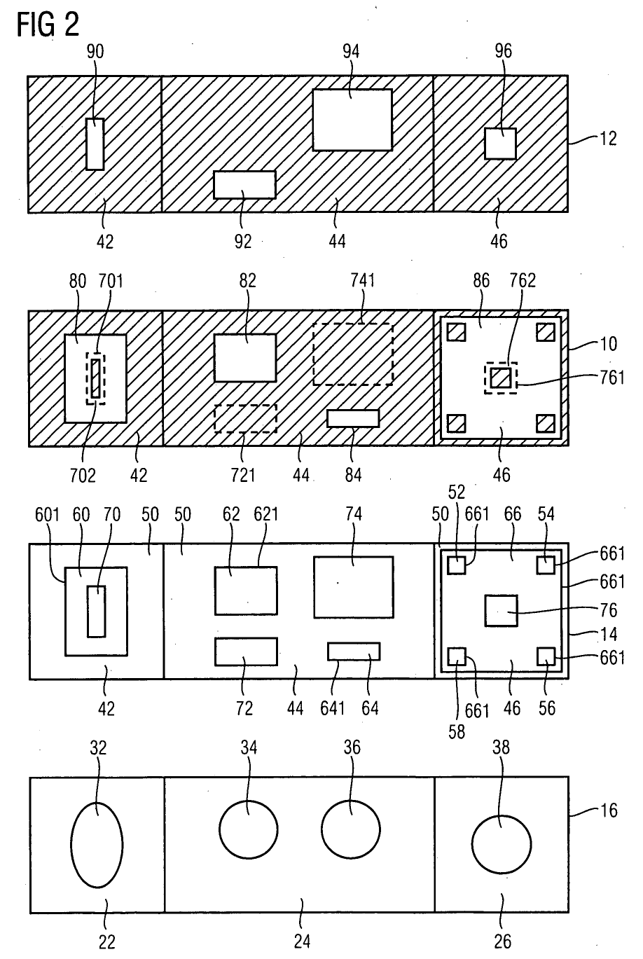

FIG. 2 is a schematic illustration of a further exemplary embodiment of the present invention. The lithography mask 14 resembles the lithography mask illustrated above with reference to FIG. 1. Correspondingly, a substrate 16 that is patterned lithographically with the aid of the lithography mask 14 also resembles the substrate described above with reference to FIG. 1. The lithography mask 14 is produced with the aid of second lithography masks, as already described above with reference to FIG. 1, the second resist mask 12 that is initially used resembling the second resist mask 12 illustrated above with reference to FIG. 1.

The fabrication of the lithography mask 14 differs from that illustrated above with reference to FIG. 1 by virtue of the form or lateral structure of the first resist mask 10. The openings 80, 86 in the sections 42, 46 provided for the production of semi-isolated or isolated structures 32, 38 encompass, besides the second regions 60, 66, not the complete third regions 70, 76 adjoining the second regions 60, 66, but rather only their edge regions 702, 762 directly adjoining the second regions 60, 66. These edge regions 702, 762 of the third regions 70, 76 which adjoin the second regions 60, 66 are preferably characterized by a predetermined constant width. As an alternative, the width of edge sections arranged parallel to one direction and the width of edge sections arranged parallel to a direction perpendicular thereto have two different predetermined values.

The first data set used for the production of the first resist mask 10 can be produced particularly simply by setting an oversize or enlargement of the magnitude of the width of the edge regions 702, 762 for the openings 80, 86 or preferably for all the openings 80, 82, 84, 86. Therefore, only the second regions 60, 62, 64, 66 or the arrangement, size and form thereof are required for the production of the first data set. In order to avoid a displacement of all those edges or margins or boundaries of the second regions 60, 62, 64, 66 with which the latter do not adjoin third regions, but rather adjoin first regions 50, 52, 54, 56, 58, the second regions 60, 62, 64, 66 are initially defined to be smaller or second regions 60, 62, 64, 66 defined to be smaller are used for the production of the first data set. This means that all the boundaries or edges 601, 621, 641, 661 with which these adjoin first regions 50, 52, 54, 56, 58 are displaced away from the first regions 50, 52, 54, 56, 58 by the width of the edge regions 702, 762. This displacement is compensated for during the subsequent operation of enlarging the second regions 60, 62, 64, 66, so that the openings 80, 82, 84, 86 defined by the first data set differ from the second regions 60, 62, 64, 66 by virtue of the edge regions 702, 762 of the third regions 70, 76 directly adjoining second regions 60, 66. This production of the first data set is advantageous particularly because the described enlargement of regions is regularly part of the functional scope of software used for creating the data sets.

Relative positional errors of the first resist mask 10 and of the second resist mask 12 up to the magnitude of the width of the edge regions 702, 762 do not have the consequence, during this fabrication of the lithography mask 14, that the nontransparent layer remains between second regions 60, 66 and third regions 70, 76 which are intended to adjoin one another.

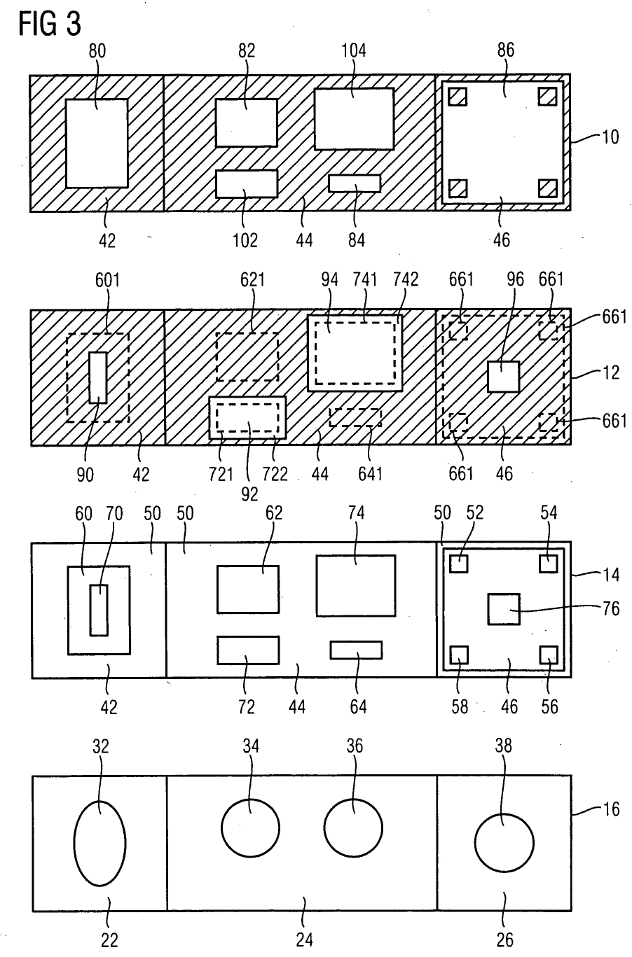

FIG. 3 is a schematic illustration of a further exemplary embodiment of the present invention. The lithography mask 14 resembles the lithography masks illustrated above with reference to FIGS. 1 and 2. Correspondingly, the substrate 16- that is patterned lithographically by means of the lithography mask 14 resembles the patterned substrates described above with reference to FIGS. 1 and 2.

However, the lithography mask 14 is fabricated differently than above with reference to FIGS. 1 and 2. Firstly, a first data set describing a first resist mask 10 and a second data set describing a second resist mask 12 are produced. The first data set defines openings 80, 82, 84, 86, 102, 104 of the first resist mask 10. The openings defined by the first data set correspond to the second regions 60, 62, 64, 66 and the third regions 70, 72, 74, 76 of the lithography mask. To put it another way, the areas of the openings 80, 82, 84, 86, 102, 104 correspond to the union set of the areas of the second regions 60, 62, 64, 66 and of the third regions 70, 72, 74, 76.

The second data set defines openings 90, 92, 94, 96 of the second resist mask 12. In this case, the openings 90, 92, 94, 96 correspond to the third regions 70, 72, 74, 76 plus edge regions 722, 742 of the first regions 50 which directly adjoin third regions 72, 74. These edge regions are preferably characterized by a predetermined width. As an alternative, the edge regions 722, 742 are characterized by a first predetermined width of sections arranged parallel to one direction and by a second predetermined width of sections of the edge regions 722, 742 which are arranged in a direction perpendicular thereto. Since third regions 70, 72, 74, 76 directly adjoin first regions 50, 52, 54, 56, 58 in the second section 44 of the lithography mask 14, the second section being provided for the production of dense structures 34, 36, it is also in the second section 44 that the openings 92, 94 are enlarged relative to the third regions 72, 74.

Under the control of the first data set, firstly a resist layer applied over the whole area on the unpatterned mask substrate is patterned. This is preferably effected, as already illustrated above with reference to FIGS. 1 and 2, with the aid of an electron beam, ion beam or laser beam or else in some other way. If necessary, the resist layer is then developed in order to remove the areas written to by the electron beam, ion beam or laser beam and thus to produce the openings 80, 82, 84, 86, 102, 104 (negative resist). As an alternative, during the development, those areas are removed which have not been altered by the electron beam, ion beam or laser beam, in order to produce the openings 80, 82, 84, 86, 102, 104 (positive resist). If the resist layer is already removed locally by the writing or irradiation, a development step can be dispensed with.

The first resist mask 10 then present is used in an etching step in order to remove the nontransparent layer of the mask substrate in the region of the openings 80, 82, 84, 86, 102, 104. The etchant used in this case preferably removes the nontransparent layer, but not the transparent material of the mask substrate, and acts isotropically or else anisotropically. The first resist mask 10 is subsequently removed.

A further resist layer is then produced over the whole area on the mask substrate and patterned laterally under the control of the second data set. This is preferably effected in a manner similar to the patterning of the first resist layer. The openings 90, 92, 94, 96 arise. The second resist mask 12 thus produced does not cover the nontransparent layer in the edge regions 722, 742 adjoining the third regions 72, 74 in the openings 92, 94. The second resist mask 12 and the nontransparent layer uncovered in the openings 92, 94 serve as an etching mask for etching the transparent material of the mask substrate in a subsequent etching step. In this case, the transparent material is removed in those regions which are covered neither by the second resist mask 12 nor by the nontransparent layer. These are the third regions 70, 72, 74, 76. The etching step removes the transparent material of the mask substrate by a thickness Δ, as described above.

The lithography mask 14 is finished after the removal of the second resist mask 12. Since the first resist mask 10, in a manner similar to that in the case of the methods illustrated above with reference to FIGS. 1 and 2, has openings 80, 86 which also encompass, besides the second regions 60, 66, the third regions 70, 76 directly adjoining the latter, this fabrication method also precludes the situation where residues of the nontransparent layer remain between second regions 60, 66 and third regions 70, 76 which are intended to directly adjoin one another, on account of a relative positional offset between the resist masks 10, 12. As illustrated above with reference to FIG. 2, a similar effect can also be obtained if the openings 80, 86 do not encompass the entire third regions 70, 76 adjoining second regions 60, 66, but rather the edge regions of the third regions.

However, the method described with reference to FIG. 3 has an additional advantage that the edges 721, 741 of the third regions 72, 74 in the second section 44 of the lithography mask 14, the second section being provided for the production of dense structures 34, 36, are defined by openings in the nontransparent layer. These openings in the nontransparent layer are produced simultaneously with the second regions 62, 64 by means of the first resist mask 10. The relative arrangement of the second and third regions 62, 64, 72, 74 in the second section 44 of the lithography mask 14, the second section being provided for the production of dense structures 34, 36, is thus exclusively defined by the first resist mask 10. Therefore, a relative offset between the resist masks 10, 12 has no influence on the relative arrangement of the second and third regions 62, 64, 72, 74 in the second section 44 of the lithography mask 14. This holds true as long as the resist masks 10, 12 are offset relative to one another by no more than the width of the edge regions 722, 742.

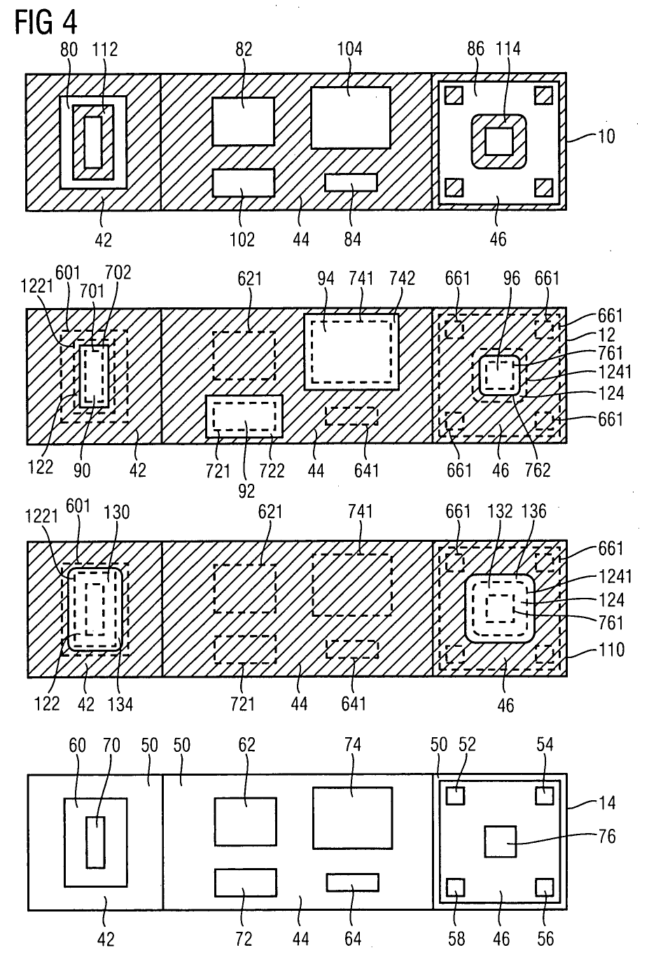

FIG. 4 is a schematic illustration of a further exemplary embodiment of the present invention. The finished lithography mask 14 and the substrate 16 (not illustrated in FIG. 4) patterned lithographically by means of the lithography mask 14 resemble those illustrated above with reference to FIGS. 1 to 3. Three resist masks 10, 12, 110 are used for the production of the lithography mask 14. The resist masks are patterned under the control of three data sets produced previously, in a manner similar to that illustrated above with reference to FIGS. 1 to 3.

A first data set describes openings 80, 82, 84, 86, 102, 104 of the first resist mask 10. These openings 80, 82, 84, 86, 102, 104 correspond with regard to their arrangement, form and size to the second regions 60, 62, 64, 66 and to the third regions 70, 72, 74, 76 of the finished lithography mask 14 minus frame-type edge regions of the second regions 60, 66 which adjoin third regions 70, 76.

A second data set, which describes the second resist mask 12 and is provided for controlling its production, defines openings 90, 92, 94, 96 of the second resist mask 12 which correspond to the third regions 70, 72, 74, 76 plus edge regions 702, 722, 742, 762—adjoining the latter—of the first regions 50 (in the second section 44) and of the second regions 60, 66 (in the first and third sections 42, 46). These edge regions are again characterized by a predetermined width or by a first predetermined width of sections parallel to a first direction and a second predetermined width of sections parallel to a second direction perpendicular thereto.

A third data set defines openings 130, 132 which correspond with regard to their arrangement, form and size to the auxiliary frames 122, 124 plus edge regions 134, 136 adjoining the latter on the outside.

The first resist mask 10 produced under the control of the first data set comprises openings 80, 86 which essentially correspond to the second regions 60, 66 and to the third regions 70, 76, but within which resist auxiliary frames 112, 114 are arranged. Said resist auxiliary frames 112, 114 correspond to the edge regions of second regions 60, 66 which directly adjoin third regions 70, 76. They are preferably characterized, in a similar manner to the edge regions 702, 722, 742, 762 characterized above with reference to FIGS. 2 and 3, by a predetermined width or by a first predetermined width of the sections parallel to a first direction and a second predetermined width of the sections parallel to a second direction perpendicular thereto.

The first lithography mask 10 serves as an etching mask, with removal of regions of the nontransparent layer of the mask substrate which are uncovered within the openings 82, 84, 86, 102, 104. In accordance with the openings 80, 82, 84, 86, 102, 104 of the first resist mask, the nontransparent layer is completely removed in the second regions 62, 64 which do not adjoin third regions and in the third regions 70, 72, 74, 76. The nontransparent layer is partly removed in the second regions 60, 66 which adjoin third regions 70, 76, auxiliary frames made from the nontransparent layer and directly adjoining the third regions 70, 76 remaining in accordance with the resist auxiliary frames 112, 114. The edges 601, 621, 641, 661, 701, 721, 741, 761 of the second and third regions 60, 62, 64, 66, 70, 72, 74, 76 and also the outer edges 1221, 1241 of the auxiliary frames 122, 124 are represented by interrupted lines in the case of the second resist mask 12 described below. The inner edges of the auxiliary frames 122, 124 correspond to the edges 701, 761 of the third regions 70, 76 directly adjoining second regions 60, 66.

After the removal of the first resist mask, the second resist mask 12 is produced under the control of the second data set in a manner similar to that already mentioned a number of times above. The mask and the regions of the nontransparent layer which are uncovered in frame-type fashion within the openings 90, 92, 94, 96 serve as an etching mask for removing a layer having the thickness Δ (see above) of the transparent material of the mask substrate. Consequently, the transparent material of the mask substrate is removed in the regions covered neither by the second resist mask 12 nor by the nontransparent layer. Consequently, the edges 701, 721, 741, 761 of the third regions 70, 72, 74, 76 patterned in this way are defined by the first resist mask 10 in the same way as the edges 601, 621, 641, 661 of the second regions 60, 62, 64, 66. As a result, the relative arrangement of the second regions 60, 62, 64, 66 and of the third regions 70, 72, 74, 76 is unambiguously defined and is not influenced by a relative offset between the first resist mask 10 and the second resist mask 12. This holds true as long as the relative offset between the first resist mask 10 and the second resist mask 12 is not greater than the width of the edge regions 702, 722, 742, 762 by which the openings 90, 92, 94, 96 are larger than the third regions 70, 72, 74, 76.

After the removal of the second resist mask 12, the third resist mask 110 is produced on the mask substrate under the control of the third data set, as already described a number of times above. Said third resist mask 110 is used as an etching mask for the removal of the auxiliary frames 122, 124. For this purpose, preferably the same etchant is used when the first resist mask 10 is transferred into the nontransparent layer, which does not remove the transparent material of the mask substrate. The finished lithography mask 14 is present after the removal of the auxiliary frames 122, 124 and of the third resist mask 110.

In a departure from the resist masks illustrated with reference to FIGS. 1 to 3, the resist masks 10, 12, 110 illustrated in FIG. 4 have not only rectangular structures, but also structures with rounded corners. A rounding of corners may already be provided in the data set controlling the production of the corresponding resist mask and/or be governed by the resolution capability of the process with which the resist layer forming the resist mask is laterally patterned. As already mentioned, the arrangement, size and form of all the second and third regions 60, 62, 64, 66, 70, 72, 74, 76 are defined exclusively by the first resist mask 10. It is desirable, therefore, to produce the first resist mask 10 with a maximum resolution. By contrast, the second resist mask 12 and the third resist mask 110 can be produced with a lower resolution. The fabrication costs for the lithography mask 14 can thereby be reduced. By way of example, the first resist mask 10 is patterned by means of an electron beam writer, while the second resist mask 12 and the third resist mask 110 are patterned by means of (visible or invisible) light and lower resolution but also lower costs. In this case, in a departure from FIG. 4, all the corners of the second and third resist masks 12, 110 are rounded.

However, a rounding of corners is also expedient insofar as a simultaneous maximum relative positional offset between the resist masks is improbable. At the same time, the rounding of corners reduces the risk of overlapping of diagonally adjacent structures, for example of the opening 96 or 132 with a first region 52, 54, 56, 58.

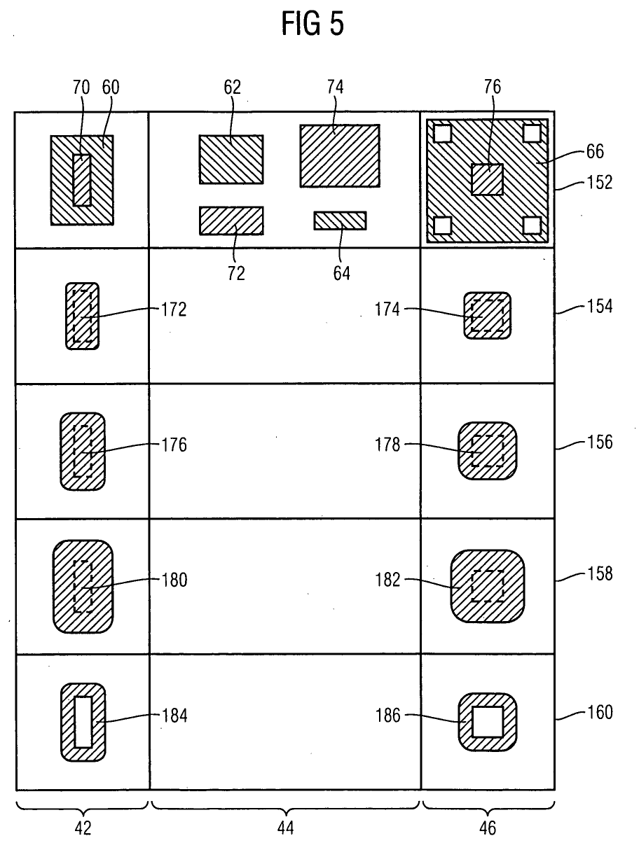

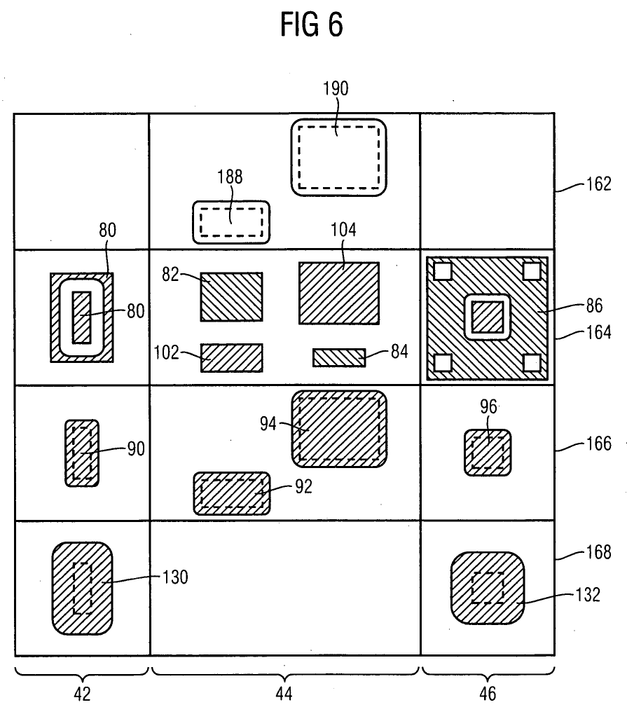

FIGS. 5 and 6 are schematic illustrations with reference to which the production of the data sets mentioned above in the descriptions of FIGS. 1 to 4 is explained below. The illustrations show row by row auxiliary data sets 152, 154, 156, 158, 160, 162 and the data sets 164, 166, 168 produced therefrom as described below, for controlling the production of resist masks. In this case, the areas defined by the data sets are illustrated in FIGS. 5 and 6. In accordance with the illustrations of the resist masks 10, 12, 110 and the lithography mask 14 in FIGS. 1 to 4, FIGS. 5 and 6 also illustrate on the outer left and on the outer right the first and third sections 42, 46 provided for the lithographic production of semi-isolated or isolated structures 32, 38. The second section 44 provided for the lithographic production of dense structures 34, 36 is in each case illustrated in the center. By way of example, FIGS. 5 and 6 illustrate the production of the data sets of the exemplary embodiment illustrated above with reference to FIG. 4.

The first auxiliary data set 152 defines the second regions 60, 62, 64, 66 identified by hatching inclined toward the left and the third regions 70, 72, 74, 76 identified by hatching inclined toward the right. The information about the arrangement, form and size of each of these second and third regions is preferably present in a single data set. As an alternative, the first auxiliary data set 152 comprises a plurality of partial data sets which in each case describe only one or a plurality of the sections 42, 44, 46 and/or define second regions 60, 62, 64, 66 or third regions 70, 72, 74, 76.

The second auxiliary data set 154 defines regions 172, 174 which emerge from the third regions 70, 76 arranged in the first section 42 or in the third section 46 or from the third regions 70, 76 directly adjoining second regions 60, 66, by enlargement by a magnitude k on all sides or by addition of a frame-type edge region having the width k. The regions 172, 174 correspond to the openings 90, 96 of the second resist mask 12 illustrated above with reference to FIG. 4.

The third auxiliary data set 156 defines regions 176, 178 which emerge from the third regions 70, 76 arranged in the first section 42 or in the third section 46 or from the third regions 70, 76 directly adjoining second regions 60, 66, by means of enlargement by a magnitude a on all sides or by addition of a directly adjoining frame-type edge region having the width a.

The fourth auxiliary data set 158 defines regions 180, 182 which emerge from the third regions 70, 76 arranged in the first section 42 or in the third section 46 or from the third regions 70, 76 directly adjoining second regions 60, 66, by means of enlargement by a magnitude a+k on all sides or by addition of a directly adjoining frame-type edge region having the width a+k. The regions 180, 182 correspond to the openings 130, 132 of the third resist mask 110 illustrated above with reference to FIG. 4.

The fifth auxiliary data set 160 defines frame-type regions 184, 186 corresponding to a subtraction of the third regions 70, 76 directly adjoining second regions 60, 66 or arranged in the first or third section 42, 46 from the regions 176, 178 of the third auxiliary data set 156. Said frame-type regions 184, 186 correspond with regard to arrangement, size and form to the resist auxiliary frames 112, 114 illustrated above with reference to FIG. 4.

The sixth auxiliary data set 162 defines regions 188, 190 which emerge from the third regions 72, 74 not directly adjoining second regions or arranged in the second section 44, by means of enlargement by the magnitude k on all sides or by addition of frame-type edge regions having the width k and adjoining these more directly. The regions 188, 190 correspond to the openings 92, 94 of the second resist masks 12 illustrated above with reference to FIGS. 3 and 4.

The first data set 164 defines regions which correspond to the openings 80, 82, 84, 86, 102, 104 of the first resist mask 10 illustrated above in FIG. 4 and are therefore provided with the same reference symbols here. These emerge from the sum or union set of the second and third regions 60, 62, 64, 66, 70, 72, 74, 76 defined in the first data set 152 minus the frame-type regions 184, 186 defined in the fifth auxiliary data set 160.

The second data set 166 defines regions which correspond to the openings 90, 92, 94, 96 of the second resist mask 12 illustrated above with reference to FIG. 4 and are therefore provided with the same reference symbols here. These emerge from a sum or union set of the regions 172, 174 defined in the second auxiliary data set 154 and the regions 188, 190 defined in the sixth auxiliary data set 162.

The third data set 168 defines regions which correspond to the openings 130, 132 of the third resist mask 110 illustrated above with reference to FIG. 4 and are therefore provided with the same reference symbols here. These regions 130, 132 emerge from the regions 180, 182 defined in the fourth auxiliary data set 158 or are identical to them.

The data sets 164, 166, 168 illustrated in FIG. 6 define the arrangement, size and form of the openings of the resist masks to be produced. In the case of a negative resist, the regions 80, 82, 84, 86, 102, 104, 90, 92, 94, 96, 130, 132 which are defined in the data sets 164, 166, 168 and are illustrated in hatched fashion in FIG. 6 are exposed or written to by means of an electron beam, ion beam or laser beam or in some other way in order (if necessary after a development step) to obtain corresponding openings in the resist layer. In the case of a positive resist, the surrounding regions, not hatched in FIG. 6, are written to or exposed instead.

The magnitude k is the maximum magnitude of a relative offset between the resist masks 10, 12, 110. The magnitude a corresponds to the width of the frame-type regions 184, 186 defined in the fifth auxiliary data set 160 or the auxiliary frames 122, 124 made from the nontransparent layer as illustrated above with reference to FIG. 4. Preferably, the magnitude a corresponds to at least double the magnitude k, a=2 k or a>2 k.

The enlarged regions 172, 174, 176, 178, 180, 182, 188, 190 and the regions 184, 186, 90, 92, 94, 96, 130, 132 derived therefrom are illustrated with rounded corners in FIGS. 5 and 6. The radii are preferably k or a or a+k. As an alternative, the enlargement is in each case effected in such a way that a rectangle without rounded corners arises.

In the exemplary embodiment illustrated with reference to FIGS. 5 and 6, the enlargement is effected in each case in all directions with the same magnitude k or a or a+k. As an alternative, the enlargement is effected in two mutually perpendicular directions with different magnitudes. This may be advantageous if it is already known that a larger relative offset between resist masks can occur in one direction than in another direction perpendicular thereto. Furthermore, it is possible to enlarge different third regions 70, 72, 74, 76 by different magnitudes k, k′ or a, a′ or a+k, a′+k′.

The dimensions of and distances between the second and third regions of the lithography mask give rise to requirements made of the minimum resolution and of the relative edge position accuracy or the maximum relative offset of the resist masks 10, 12, 110. From a minimum distance between adjacent second and third regions 62, 64, 72, 74 in the second section 44 having the size d it follows that the maximum relative offset between the first resist mask 10 and the second resist mask 12 should be d/2 and the magnitude k should likewise be k=d/2. It furthermore follows that the resolution should be better than d/2. It can be seen from the consideration of the second and third regions 60, 70 in the first section 42 of the lithography mask 14 that the magnitude a should be half of the minimum distance on all sides between the third region 70 and the first region 50.

Typical values are k=15 nm, a=35 nm . . . 40 nm for a minimum distance between the third region 70 and the first region 50 in the first section 42 of the lithography mask of the order of magnitude of 70 nm to 80 nm. This results in suitability for a lithographic imaging of the lithography mask 14 onto a substrate 16 by means of a wavelength of 193 nm.

As already mentioned, in a departure from the illustrations in the figures, lithography masks 14 according to the present invention or lithography masks 14 produced according to the present invention may have a significantly greater number of second and third regions 60, 62, 64, 66, 70, 72, 74, 76 for the production of a significantly larger number of structures 32, 34, 36, 38 in a larger number of sections 42, 44, 46. The arrangement, form and size of each individual structure 32, 34, 36, 38 and of the second and third regions provided for its lithographic production may also deviate considerably from the illustrations in the figures. Instead of the passage holes illustrated in the figures, it is also possible to produce lithographically other structures, for example trenches or other linear structures.

In the exemplary embodiments illustrated above, the thickness of the transparent material is reduced in the third regions 70, 72, 74, 76. For this purpose, the mask substrate may have a layer having the above-described thickness Δ which can be etched selectively, so that the thickness Δ of the removed layer is given largely independently of etching parameters by the thickness of the layer that can be etched selectively. As an alternative, the thickness Δ is set by the etching parameters such as etchant, time, temperature and concentration of the medium. Furthermore, it is possible to change the thickness Δ in the third regions 70, 72, 74, 76 not by means of material removal but rather by local application of additional material, or to locally modify the optical thickness of the mask substrate by means of a local alteration of the refractive index.

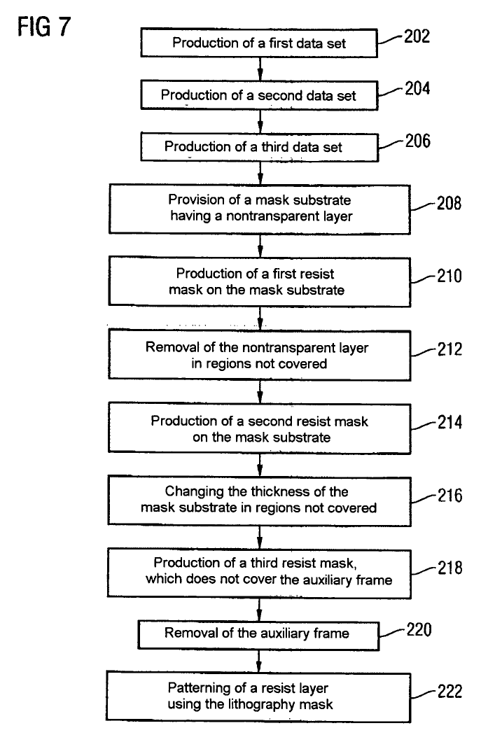

FIG. 7 describes a schematic flow diagram of a method according to the invention for fabricating a lithography mask and for fabricating a semiconductor component. A first, second and third step 202, 204, 206 involve production of a first data set, a second data set and a third data set, respectively, which are provided for controlling the patterning of three resist masks. A fourth step 208 involves the provision of a mask substrate having a nontransparent layer on a transparent or semitransparent carrier layer. A fifth step 210 involves the production of a first resist mask on the mask substrate under the control of the first data set produced in the first step 202. A sixth step 212 involves the removal of the nontransparent layer in the regions not covered by the first resist mask. A seventh step 214 involves the production of a second resist mask on the mask substrate under the control of the second data set produced in the second step 204. An eighth step 216 involves changing the thickness of the mask substrate in the regions covered neither by the second resist mask nor by the nontransparent layer. A ninth step 218 involves the production of a third resist mask under the control of the third data set produced in the third step 206, which third resist mask does not cover an auxiliary frame produced from the nontransparent layer in the sixth step 212. The auxiliary frame is removed in a tenth step 220. With the aid of the lithography mask produced in this way, an eleventh step 222 involves lithographically patterning a resist layer on a substrate in order to fabricate a semiconductor component from the substrate.

What is claimed is:

1. A lithography mask having first regions, in which the lithography mask has a nontransparent layer, and second and third regions which differ in terms of the optical thickness of the lithography mask and in which the lithography mask is at least semitransparent, for lithographic patterning of a resist layer on a substrate, comprising:
a first section having a multiplicity of second regions and a multiplicity of third regions, which are arranged alternately and surrounded by a first region, for lithographic production of resist openings at distances which are less than a predetermined limit distance; and
a second section having a multiplicity of third regions, each of which is surrounded by a second region surrounded by a multiply contiguous first region, for the lithographic production of resist openings at distances which are greater than a predetermined limit distance.

2. The lithography mask as claimed in claim 1, in which, in the first section, the third region is arranged closest adjacent to each second region and the second region is arranged closest adjacent to each third region.

3. The lithography mask as claimed in claim 1, wherein
the second regions of the multiplicity of second regions of the first section and the third regions of the multiplicity of third regions of the first section are in each case singly contiguous, and
each third region of the multiplicity of third regions of the second section is singly contiguous and surrounded by a respective multiply contiguous second region.

4. The lithography mask as claimed in claim 1, wherein the resist openings to be produced by the lithography mask being provided for the production of passage holes or trenches in the substrate.

5. The lithography mask as claimed in claim 1, in which the optical thicknesses of the lithography mask in adjacent second and third regions differ such that light transmitted through a second region has a phase difference in the range of 120° to 240° relative to light transmitted through an adjacent third region.

6. A method for the production of a lithography mask having first regions, in which the lithography mask has a nontransparent layer, and second and third regions, which differ in terms of optical thickness of the lithography mask, and in which the lithography mask is at least semitransparent, for lithographic patterning of a resist layer on a substrate, comprising:
producing a multiplicity of second regions and a plurality of third regions in a first section, which are arranged alternately and surrounded by a first region, for lithographic production of resist openings at distances which are less than a predetermined limit distance; and
producing a multiplicity of third regions in a second section, each of which is surrounded by a second region surrounded by a multiply contiguous first region, for the lithographic production of resist openings at distances which are greater than a predetermined limit distance.

7. A method for the production of a lithography mask having a first region, in which the lithography mask has a nontransparent layer, and having a second and a third region, in which the lithography mask is at least semitransparent and has different optical thicknesses, comprising:
a) providing a mask substrate having the nontransparent layer;
b) producing a first resist mask on the mask substrate;
c) removing the nontransparent layer in the regions not covered by the first resist mask;
d) producing a second resist mask on the mask substrate; and
e) changing the optical thickness of the mask substrate in a third region which is covered neither by the second resist mask nor by the nontransparent layer,
the first resist mask being produced in step b) such that it does not cover a third region of the lithography mask at least in a peripheral edge region.

8. The method as claimed in claim 7, in which step b) is performed with a higher lateral resolution than step d).

9. The method as claimed in claim 7, in which the steps are performed in an order a), d), e), b), c), further comprising, performed between steps d) and e):
f) removing the nontransparent layer in the regions not covered by the second resist mask.

10. The method as claimed in claim 7, in which the steps are performed in an order a), b), c), d), e),
step b) further including the production of openings in the first resist mask which correspond to second and third regions to be produced,
step c) further including the removal of the nontransparent layer in second and third regions, and
step d) further including the production of the second resist mask such that it covers second regions which are no longer covered by the nontransparent layer.

11. The method as claimed in claim 7, in which the steps are performed in an order a), b), c), d), e),
step b) further including the production of the first resist mask with a resist auxiliary frame, the inner edge of which corresponds to an outer periphery of a third region to be produced,
in step c) a frame-type region of the nontransparent layer, which region corresponds to the resist auxiliary frame, remaining as auxiliary frame on the mask substrate, and
step d) further comprising the production of the second resist mask with an opening, an edge of which is spaced apart from an inner edge of an auxiliary frame, so that the opening frees a multiply contiguous partial region of the auxiliary frame,
further comprising, following step e):
g) removing the auxiliary frame.

12. The method as claimed in claim 11, in which step g) includes the production of a third resist mask with an opening, which frees the auxiliary frame.

13. The method as claimed in claim 7, in which step e) includes the reduction of optical thickness of the lithography mask in the third regions to an extent such that light transmitted through a second region and light transmitted through an adjacent third region, having a same predetermined wavelength, have a phase difference within a predetermined interval.

14. The method as claimed in claim 13, in which the predetermined interval comprises phase differences of between 120° and 240°.

15. The method as claimed in claim 7, for the production of a lithography mask, the lithography mask having first regions, in which the lithography mask has a nontransparent layer, and second and third regions which differ in terms of the optical thickness of the lithography mask and in which the lithography mask is at least semitransparent, for lithographic patterning of a resist layer on a substrate, comprising:
a first section having a multiplicity of second regions and a multiplicity of third regions, which are arranged alternately and surrounded by a first region, for lithographic production of resist openings at distances which are less than a predetermined limit distance; and
a second section having a multiplicity of third regions, each of which is surrounded by a second region surrounded by a multiply contiguous first region, for the lithographic production of resist openings at distances which are greater than a predetermined limit distance.

16. A method for fabricating a semiconductor component, a lithography mask having first regions, in which the lithography mask has a nontransparent layer, and second and third regions which differ in terms of the optical thickness of the lithography mask and in which the lithography mask is at least semitransparent, comprising:
a first section having a multiplicity of second regions and a multiplicity of third regions, which are arranged alternately and surrounded by a first region, for lithographic production of resist openings at distances which are less than a predetermined limit distance; and
a second section having a multiplicity of third regions, each of which is surrounded by a second region surrounded by a multiply contiguous first region, for the lithographic production of resist openings at distances which are greater than a predetermined limit distance, and
being used to lithographically pattern a resist layer on a substrate.

17. A method for producing a first data set for controlling patterning of a first resist mask, and a second data set for controlling the patterning of a second resist mask, the first resist mask and the second resist mask being provided for the production of a lithography mask having first, second and third regions, the lithography mask having a nontransparent layer in the first regions and being at least semitransparent in the second and third regions and the second and third regions differing in terms of optical thickness of the lithography mask, comprising:
producing the first data set such that it comprises at least partial regions of the second regions and edge regions of third regions which at least directly adjoin second regions; and
producing the second data set such that it comprises the third regions.

18. The method as claimed in claim 17, the first data set being produced such that it comprises the second regions and edge regions of third regions which at least directly adjoin second regions.

19. The method as claimed in claim 17, the first data set being produced such that it comprises the second and the third regions, and
the second data set being produced such that it comprises the third regions and the edge regions of first regions which directly adjoin third regions.

20. The method as claimed in claim 17, the first data set being produced such that it comprises the second regions which do not adjoin third regions, the second regions which adjoin third regions, in each case without a first edge region, adjoining the third region, with a first edge width, and the third region, and
the second data set being produced such that it comprises the third regions and second edge regions of first or second regions which adjoin the third regions, with a second edge width, the second edge width being smaller than the first edge width, and further comprising:
producing a third data set such that it comprises the two first edge regions plus third edge regions which adjoin the second edge regions with a third edge width.

21. The method as claimed in claim 7, in which data sets are produced by producing the first data set such that it comprises at least partial regions of the second regions and edge regions of third regions which at least directly adjoin second regions, and the second data set such that it comprises the third regions, and in which the resist masks are produced with the aid of the data sets.
